(19) United States
(12) Patent Application Publication
(10) Pub. No.: US 2006/0249739 A1
(43) Pub. Date: Nov. 9, 2006

(54) Multi-wavelength white light emitting diode

(76) Inventors: Bily Wang, Hsin Chu City (TW); Jonnie Chuang, Pan Chiao City (TW); Chuan-Fa Lin, Shu Lin City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/416,144

(22) Filed: May 3, 2006

(30) Foreign Application Priority Data
May 6, 2005 (TW) 94114756

(51) Int. Cl. H01L 33/00

(52) U.S. Cl. 257/88; 257/89; 257/E33.03

(57) ABSTRACT

A multi-wavelength white light emitting diode uses a UV light emitting diode chip and a blue light emitting diode chip to excite a red phosphor and a green phosphor and generates a white light emitting diode having good color rendering. The multi-wavelength white light emitting diode uses a UV light emitting diode chip that emits light having a wavelength of between 350˜430 nm to excite a red phosphor to emit red light having a wavelength of between 600˜700 nm. The present invention then uses a blue light emitting diode chip that emits light having a wavelength between of 400˜500 nm to emit blue light and uses the blue light emitting diode chip to excite a green phosphor to emit green light having a wavelength of between 490˜560 nm. Mixing the red light, the blue light and the green light forms a white light.

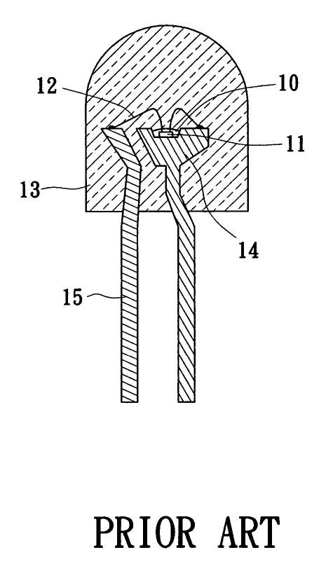

### BACKGROUND OF THE INVENTION

1. Field of the Invention

The present invention relates to a multi-wavelength white light emitting diode. In particular, this invention uses a UV light emitting diode chip and a blue light emitting diode chip to excite a red phosphor and a green phosphor and generates a white light emitting diode having good color rendering.

2. Description of the Related Art

Technological developments with light emitting diodes (LEDs), such as the improvement of their quality, efficiency, life and color rendering, have led to LEDs being all around us—they are commonly applied in, for example, traffic signs, cell phones, Christmas ornaments and lighting apparatuses, etc. Currently, a white light emitting diode cannot be produced by directly using a light emitting diode chip that emits white light. The general method uses a light emitting diode chip that emits color light and excites a phosphor having a specified wavelength. These two wavelength lights are then mixed to emit white light.

To produce a white light emitting diode, one method combines a red light emitting diode chip, a green light emitting diode chip and a blue light emitting diode chip with a predetermined ratio. Another method uses a blue light emitting diode chip or a UV light emitting diode chip and a specified phosphor.

The FIGURE shows U.S. Pat. No. 5,998,925, titled “Light Emitting Device Having A Nitride Compound Semiconductor And A Phosphor Containing A Garnet Fluorescent Material.” The invention uses a nitride compound semiconductor to emit blue light and excites a phosphor containing a garnet fluorescent material to emit yellow light. The blue light and the yellow light are then mixed to emit white light. The light emitting device comprises a phosphor 10, a light emitting element 11, a connecting wire 12, a protection mask 13 and two conducting-wire pins 14 and 15.

TW publication patent No. 200417064, titled “A Method For Producing A White Light Emitting Diode Source Excited By A UV Light” is another prior art. A white light is produced by using a yellow-white phosphor that has a flat-broad wavelength band and is excited by a UV light emitting diode chip (with a wavelength of between 380˜400 nm), and a blue light emitting diode chip.

The white light emitting diode of the prior art uses a blue light emitting diode to excite a yellow phosphor and generates a yellow light. The yellow light and the blue light are then mixed to emit high luminance white light. When the white light emitting diode is used as a lighting apparatus any objects upon which it shines will have a yellow or blue tint.

In order to improve the color rendering, the prior art adopted a UV light emitting diode to excite a red phosphor, a green phosphor and a blue phosphor. When we select the phosphors with an appropriate ratio to emit white light, it is necessary to meet a condition—the exciting light must be absorbable by these phosphors and the absorbability index of the phosphors must be similar. This requirement increases the difficulty of choosing suitable phosphors.

### SUMMARY OF THE INVENTION

In one particular aspect of the present invention, a multi-wavelength white light emitting diode uses a UV light emitting diode chip and a blue light emitting diode chip to excite a red phosphor and a green phosphor and generates a white light emitting diode. The multi-wavelength white light emitting diode of the present invention increases number of options available when choosing phosphors and enhances color rendering and lighting efficiency.

The multi-wavelength white light emitting diode of the present invention uses a UV light emitting diode chip that emits light having a wavelength between 350˜430 nm to excite a red phosphor so as to emit red light having a wavelength between 600˜700 nm. The present invention then uses a blue light emitting diode chip that emits light having a wavelength between 400˜500 nm to emit blue light. The blue light emitting diode chip that emits light with a wavelength between 400˜500 nm, is then used to excite green phosphor to emit green light having a wavelength between 490˜560 nm. Mixing the red light, the blue light and the green light forms a white light.

The multi-wavelength white light emitting diode of the present invention also uses a UV light emitting diode chip that emits light having a wavelength between 350˜430 nm to excite a red phosphor to emit red light having a wavelength between 600˜700 nm. The present invention then uses a blue light emitting diode chip that emits light having a wavelength between 400˜500 nm to emit blue light. The blue light emitting diode chip that emits light having a wavelength between 400˜500 nm, is then used to excite a green phosphor to emit green light having a wavelength between 490˜560 nm and a yellow phosphor to emit yellow light having a wavelength between 550˜600 nm. Mixing the red light, the blue light, the green light and the yellow light forms a white light.

The multi-wavelength white light emitting diode of the present invention further uses a UV light emitting diode chip that emits light having a wavelength between 350˜430 nm to excite a red phosphor to emit red light having a wavelength between 600˜700 nm and a green phosphor to emit green light having a wavelength between 490˜560 nm. The present invention then uses a blue light emitting diode chip that emits light having a wavelength between 400˜500 nm to emit blue light. Mixing the red light, the blue light and the green light forms a white light.

The multi-wavelength white light emitting diode of the present invention further uses a UV light emitting diode chip that emits light having a wavelength between 350˜430 nm to excite a red phosphor to emit red light having a wavelength between 600˜700 nm and a green phosphor to emit green light having a wavelength between 490˜560 nm. The present invention then uses a blue light emitting diode chip that emits light having a wavelength between 400˜500 nm to emit blue light. The blue light emitting diode chip that emits light having a wavelength between 400˜500 nm is then used to excite a yellow phosphor to emit yellow light having a wavelength between 550˜600 nm. Mixing the red light, the blue light, the green light and the yellow light forms a white light.

For further understanding of the invention, reference is made to the following detailed description illustrating the embodiments and examples of the invention. The description is only for illustrating the invention and is not intended to be considered limiting of the scope of the claim.

### BRIEF DESCRIPTION OF THE DRAWINGS

The drawings included herein provide a further understanding of the invention. A brief introduction of the drawings is as follows:

The FIGURE is a schematic diagram of a white light emitting diode of the prior art.

### DETAILED DESCRIPTION OF THE PREFERRED EMBODIMENTS

The first embodiment of a multi-wavelength white light emitting diode of the present invention uses a UV light emitting diode chip that emits light having a wavelength between 350˜430 nm to excite a red phosphor to emit red light having a wavelength between 600˜700 nm. The present invention then uses a blue light emitting diode chip that emits light having a wavelength between 400˜500 nm to emit blue light. The blue light emitting diode chip that emits light having a wavelength between 400˜500 nm is then used to excite a green phosphor to emit green light having a wavelength between 490˜560 nm. Mixing the red light, the blue light and the green light forms a white light.

The UV light emitting diode chip and the blue light emitting diode chip are made of a nitride compound semiconductor. The UV light emitting diode chip and the blue light emitting diode chip can be separated or integrated into a bi-wavelength single chip.

The chemical composition of red phosphor is Y202S:Eu, YV04:Eu, Y(V,P,B)04:Eu, Ynb04:Eu, Yta04:Eu or other phosphors that can be excited by UV light to emit red light. The chemical composition of green phosphor is SrGa₂S₄:Eu, Ca₈EuMnMg(SiO₄)C₁₂ or other phosphors that can be excited by blue light to emit green light.

The second embodiment of a multi-wavelength white light emitting diode of the present invention also uses a UV light emitting diode chip that emits light having a wavelength between 350˜430 nm to excite a red phosphor to emit red light having a wavelength between 600˜700 nm. The present invention then uses a blue light emitting diode chip that emits light having a wavelength between 400˜500 nm to emit blue light. The blue light emitting diode chip that emits light having a wavelength between 400˜500 nm is then used to excite a green phosphor to emit green light having a wavelength between 490˜560 nm and a yellow phosphor to emit yellow light having a wavelength between 550˜600 nm. Mixing the red light, the blue light, the green light and the yellow light forms a white light.

The UV light emitting diode chip and the blue light emitting diode chip are made of a nitride compound semiconductor. The UV light emitting diode chip and the blue light emitting diode chip can be separated or integrated into a bi-wavelength single chip.

The chemical composition of red phosphor is Y202S:Eu, YV04:Eu, Y(V,P,B)04:Eu, Ynb04:Eu, Yta04:Eu or other phosphors that can be excited by UV light to emit red light. The chemical composition of green phosphor is SrGa₂S₄:Eu, Ca₈EuMnMg(SiO₄)C₁₂ or other phosphors that can be excited by blue light to emit green light. The chemical composition of yellow phosphor is YAG:Ce, TbAG:Ce or other phosphors that can be excited by blue light to emit yellow light.

The third embodiment of a multi-wavelength white light emitting diode of the present invention further uses a UV light emitting diode chip that emits light having a wavelength between 350˜430 nm to excite a red phosphor to emit red light having a wavelength between 600˜700 nm and a green phosphor to emit green light having a wavelength between 490˜560 nm. The present invention then uses a blue light emitting diode chip that emits light having a wavelength between 400˜500 nm to emit blue light. Mixing the red light, the blue light and the green light forms a white light.

The UV light emitting diode chip and the blue light emitting diode chip are made of a nitride compound semiconductor. The UV light emitting diode chip and the blue light emitting diode chip can be separated or integrated into a bi-wavelength single chip.

The chemical composition of red phosphor is Y202S:Eu, YV04:Eu, Y(V,P,B)04:Eu, Ynb04:Eu, Yta04:Eu or other phosphors that can be excited by UV light to emit red light. The chemical composition of green phosphor is SrGa₂S₄:Eu, Ca₈EuMnMg(SiO₄)C₁₂ or other phosphors that can be excited by blue light to emit green light.

The fourth embodiment of a multi-wavelength white light emitting diode of the present invention further uses a UV light emitting diode chip that emits light having a wavelength between 350˜430 nm to excite a red phosphor to emit red light having a wavelength between 600˜700 nm and a green phosphor to emit green light having a wavelength between 490˜560 nm. The present invention then uses a blue light emitting diode chip that emits light having a wavelength between 400˜500 nm to emit blue light. The blue light emitting diode chip that emits light having a wavelength between 400˜500 nm is then used to excite a yellow phosphor to emit yellow light having a wavelength between 550˜600 nm. Mixing the red light, the blue light, the green light and the yellow light forms a white light.

The UV light emitting diode chip and the blue light emitting diode chip are made of a nitride compound semiconductor. The UV light emitting diode chip and the blue light emitting diode chip can be separated or integrated into a bi-wavelength single chip.

The chemical composition of red phosphor is Y202S:Eu, YV04:Eu, Y(V,P,B)04:Eu, Ynb04:Eu, Yta04:Eu or other phosphors that can be excited by UV light to emit red light. The chemical composition of green phosphor is SrGa₂S₄:Eu, Ca₈EuMnMg(SiO₄)C₁₂ or other phosphors that can be excited by blue light to emit green light. The chemical composition of yellow phosphor is YAG:Ce, TbAG:Ce or other phosphors that can be excited by blue light to emit yellow light.

The packaging type of a multi-wavelength white light emitting diode of the present invention can be lamp, surface-mounted device (SMD) or chip on board (COB), etc.

The present invention has the following characteristics:

1. The lighting efficiency is excellent. The present invention adopts a short-wavelength light, such as a UV light emitting diode chip, to excite phosphor. As such, the lighting efficiency is increased.

2. The color rendering is good. The present invention uses a UV light emitting diode and a blue light emitting diode to excite a red phosphor and a green phosphor, and generate red light, green light and blue light. Mixing these three lights to obtain white light enhances the color rendering.

3. The number of phosphors that can be used is higher. The present invention utilizes the characteristics of light emitting diodes and phosphors to generate red light, green light and blue light. Through this method, the number of available options when choosing phosphors increases due to the fact that the limitations, based upon the absorbability index of phosphor, are smaller.

The description above only illustrates specific embodiments and examples of the invention. The invention should therefore cover various modifications and variations made to the herein-described structure and operations of the invention, provided they fall within the scope of the invention as defined in the following appended claims.

What is claimed is:

1. A multi-wavelength white light emitting diode, comprising:
a UV light emitting diode chip, emitting a light having a wavelength between 350˜430 nm;
a red phosphor, excited by the UV light emitting diode chip to emit red light;
a blue light emitting diode chip, emitting a blue light having a wavelength between 400˜500 nm; and
a green phosphor, excited by the blue light emitting diode chip to emit green light;
wherein, mixing the red light, the blue light and the green light forms a white light emitting diode.

2. The multi-wavelength white light emitting diode of claim 1, wherein the UV light emitting diode chip is made of a nitride compound semiconductor.

3. The multi-wavelength white light emitting diode of claim 1, wherein the blue light emitting diode chip is made of a nitride compound semiconductor.

4. The multi-wavelength white light emitting diode of claim 1, wherein the UV light emitting diode chip and the blue light emitting diode chip are integrated into a bi-wavelength single chip.

5. The multi-wavelength white light emitting diode of claim 1, wherein the chemical composition of the red phosphor is Y202S:Eu, YV04:Eu, Y(V,P,B)04:Eu, Ynb04:Eu or Yta04:Eu.

6. The multi-wavelength white light emitting diode of claim 1, wherein the chemical composition of the green phosphor is SrGa₂S₄:Eu or Ca₈EuMnMg(SiO₄)C₁₂.

7. The multi-wavelength white light emitting diode of claim 1, wherein the wavelength of the red light is between 600˜700 nm.

8. The multi-wavelength white light emitting diode of claim 1, wherein the wavelength of the red light is between 490˜560 nm.

9. A multi-wavelength white light emitting diode, comprising:
a UV light emitting diode chip, emitting a light having a wavelength between 350˜430 nm;
a red phosphor, excited by the UV light emitting diode chip to emit a red light;
a blue light emitting diode chip, emitting a blue light having a wavelength between 400˜500 nm; and
a green phosphor, excited by the blue light-emitting diode chip to emit a green light;
a yellow phosphor, excited by the blue light-emitting diode chip to emit a yellow light;
wherein, mixing the red light, the blue light, the green light and the yellow light forms a white light.

10. The multi-wavelength white light emitting diode of claim 9, wherein the UV light emitting diode chip is made of a nitride compound semiconductor.

11. The multi-wavelength white light emitting diode of claim 9, wherein the blue light emitting diode chip is made of a nitride compound semiconductor.

12. The multi-wavelength white light emitting diode of claim 9, wherein the UV light emitting diode chip and the blue light emitting diode chip are integrated into a bi-wavelength single chip.

13. The multi-wavelength white light emitting diode of claim 9, wherein the chemical composition of the red phosphor is Y202S:Eu, YV04:Eu, Y(V,P,B)04:Eu, Ynb04:Eu or Yta04:Eu.

14. The multi-wavelength white light emitting diode of claim 9, wherein the chemical composition of the green phosphor is SrGa₂S₄:Eu or Ca₈EuMnMg(SiO₄)C₁₂.

15. The multi-wavelength white light emitting diode of claim 9, wherein the chemical composition of the yellow phosphor is YAG:Ce or TbAG:Ce.

16. The multi-wavelength white light emitting diode of claim 9, wherein the wavelength of the red light is between 600˜700 nm.

17. The multi-wavelength white light emitting diode of claim 9, wherein the wavelength of the red light is between 490˜560 nm.

18. The multi-wavelength white light emitting diode of claim 9, wherein the wavelength of the yellow light is between 550˜600 nm.

19. A multi-wavelength white light emitting diode, comprising:
a UV light emitting diode chip, emitting a light having a wavelength between 350˜430 nm;
a red phosphor, excited by the UV light emitting diode chip to emit a red light;
a green phosphor, excited by the UV light emitting diode chip to emit a green light; and
a blue light emitting diode chip, emitting a blue light having a wavelength between 400˜500 nm;
wherein, mixing the red light, the blue light and the green light forms a white light.

20. The multi-wavelength white light emitting diode of claim 19, wherein the UV light emitting diode chip is made of a nitride compound semiconductor.

21. The multi-wavelength white light emitting diode of claim 19, wherein the blue light emitting diode chip is made of a nitride compound semiconductor.

22. The multi-wavelength white light emitting diode of claim 19, wherein the UV light emitting diode chip and the blue light emitting diode chip are integrated into in a bi-wavelength single chip.

23. The multi-wavelength white light emitting diode of claim 19, wherein the chemical composition of the red phosphor is Y202S:Eu, YV04:Eu, Y(V,P,B)04:Eu, Ynb04:Eu or Yta04:Eu.

24. The multi-wavelength white light emitting diode of claim 19, wherein the chemical composition of the green phosphor is SrGa₂S₄:Eu or Ca₈EuMnMg(SiO₄)C₁₂.

25. The multi-wavelength white light emitting diode of claim 19, wherein the wavelength of the red light is between 600˜700 nm.

26. The multi-wavelength white light emitting diode of claim 19, wherein the wavelength of the red light is between 490˜560 nm.

27. A multi-wavelength white light emitting diode, comprising:
a UV light emitting diode chip, emitting a light having a wavelength between 350˜430 nm;
a red phosphor, excited by the UV light emitting diode chip to emit a red light;
a green phosphor, excited by the UV light emitting diode chip to emit a green light;
a blue light emitting diode chip, emitting a blue light having a wavelength between 400˜500 nm; and
a yellow phosphor, excited by the blue light emitting diode chip to emit a yellow light;
wherein, mixing the red light, the blue light, the green light and the yellow light forms a white light.

28. The multi-wavelength white light emitting diode of claim 27, wherein the UV light emitting diode chip is made of a nitride compound semiconductor.

29. The multi-wavelength white light emitting diode of claim 27, wherein the blue light emitting diode chip is made of a nitride compound semiconductor.

30. The multi-wavelength white light emitting diode of claim 27, wherein the UV light emitting diode chip and the blue light emitting diode chip are integrated into a bi-wavelength single chip.

31. The multi-wavelength white light emitting diode of claim 27, wherein the chemical composition of the red phosphor is Y202S:Eu, YV04:Eu, Y(V,P,B)04:Eu, Ynb04:Eu or Yta04:Eu.

32. The multi-wavelength white light emitting diode of claim 27, wherein the chemical composition of the green phosphor is SrGa₂S₄:Eu or Ca₈EuMnMg(SiO₄)C₁₂.

33. The multi-wavelength white light emitting diode of claim 27, wherein the chemical composition of the yellow phosphor is YAG:Ce or TbAG:Ce.

34. The multi-wavelength white light emitting diode of claim 27, wherein the wavelength of the red light is between 600˜700 nm.

35. The multi-wavelength white light emitting diode of claim 27, wherein the wavelength of the red light is between 490˜560 nm.

36. The multi-wavelength white light emitting diode of claim 27, wherein the wavelength of the yellow light is between 550˜600 nm.
